(19) United States
(12) Patent Application Publication
(10) Pub. No.: US 2010/0171182 A1
(43) Pub. Date: Jul. 8, 2010

(54) METHOD OF FORMING A SEMICONDUCTOR DEVICE HAVING SELECTIVE STRESS RELAXATION OF ETCH STOP LAYER

(76) Inventors: Dong-Suk Shin, Yongin-si (KR); Pan-Kwi Park, Suwon-si (KR); Ha-Jin Lim, Seoul (KR); Joo-Chan Kim, Suwon-si (KR)

Correspondence Address: F. CHAU & ASSOCIATES, LLC, 130 WOODBURY ROAD, WOODBURY, NY, 11797, US

(21) Appl. No.: 12/652,426

(22) Filed: Jan. 5, 2010

(30) Foreign Application Priority Data
Jan. 7, 2009 (KR) 10-2009-000115

(51) Int. Cl. H01L 27/092; H01L 21/3115

(52) U.S. Cl. 257/369; 438/783; 257/E27.062; 257/E21.248

(57) ABSTRACT

A strained semiconductor device includes a first plurality of transistors spaced with a first gate pitch, a second plurality of transistors spaced with a second gate pitch greater than the first gate pitch, and an etch stop layer disposed on the first and second pluralities of transistors. The etch stop layer between each of the second plurality of transistors has a greater proportion of a stress-altering material than the etch stop layer between each of the first plurality of transistors.

### CROSS-REFERENCE TO RELATED APPLICATION

This application claims under 35 U.S.C. §119 priority to and the benefit of Korean Patent Application No. P2009-0001155, filed on Jan. 7, 2009, in the Korean Intellectual Property Office, the entire content of which is incorporated by reference herein.

### BACKGROUND

1. Technical Field

The present disclosure relates to semiconductor devices, and, more particularly, to semiconductor devices having improved transistor performance uniformity resulting from stress induced by an etch stop layer (ESL).

2. Discussion of Related Art

In recent years the semiconductor industry has been striving to make semiconductors smaller and faster. However, continued scaling does not automatically make the scaled transistor faster because of scaling limitations, such as gate oxide (GOX) leakage current and short channel effect (i.e., the failure of normal operation as a result of making the gate length small). As such, improving performance with or without scaling has become an emerging requirement.

One approach for doing this for high performance semiconductor devices has been to increase carrier (electron and/or hole) mobilities by introducing an appropriate stress/strain into the semiconductor device, whereby bonds between crystal's atoms are physically elongated or compressed. In particular, the etch stop layer as a stressor has received much attention due to its relative simplicity and its demonstrated potential for large performance gains caused by carrier mobility enhancement.

### SUMMARY

In accordance with exemplary embodiments of the present inventive concept, methods and apparatuses for fabricating semiconductor devices having selective stress relaxation of an etch stop layer is provided.

In accordance with an exemplary embodiment, a strained semiconductor device includes a first plurality of transistors spaced with a first gate pitch, a second plurality of transistors spaced with a second gate pitch greater than the first gate pitch, and an etch stop layer disposed on the first and second pluralities of transistors. The etch stop layer between each of the second plurality of transistors has a different proportion of a stress-altering material than the etch stop layer between each of the first plurality of transistors.

The etch stop layer between each of the first plurality of transistors may have substantially the same stress as the etch stop layer between each of the second plurality of transistors.

Portions of the etch stop layer shadowed from an oblique angle may have a lesser proportion of a stress-altering material than portions of the etch stop layer that are not shadowed from the oblique angle.

The etch stop layer between each of the first plurality of transistors may have a lesser proportion of germanium (Ge) than the etch stop layer between each of the second plurality of transistors.

The transistors may be negative channel field effect transistors (NFETs).

The ESL may include an upper ESL disposed on a lower ESL, and the upper ESL may have a greater proportion of a stress-altering material than the lower ESL.

The upper ESL may have a stress reduction relative to the lower ESL.

The upper ESL may have more germanium (Ge) relative to the lower ESL.

The upper ESL may be about half as thick as the lower ESL.

The first and second pluralities of transistors may be NFETs disposed on substrate having a first orientation, the device further including positive channel field effect transistors (PFETs) disposed on a substrate having a second orientation.

The second orientation may be about 45 degrees offset from the first orientation.

The first substrate may have a normal “110” orientation and the second substrate may have a rotated “100” orientation.

The first and second pluralities of transistors may be NFETs having a tensile ESL. The device may further include PFETs on a same substrate as the NFETs. The PFETs may have a compressive ESL.

The tensile and compressive ESLs may have the same ion implantation for stress relaxation.

The ion may be Ge.

In accordance with an exemplary embodiment of the present inventive concept a method of manufacturing a strained semiconductor device is provided. A first plurality of transistors is formed spaced apart with a first gate pitch. A second plurality of transistors is formed spaced with a second gate pitch greater than the first gate pitch. An etch stop layer on is deposited on the first and second pluralities of transistors. The etch stop layer is implanted from an oblique angle with a stress-altering material.

The oblique angle may be about 70 degrees for a 45 nm device having transistors with 1X and 2X gate pitches.

A third plurality of transistors may be formed spaced apart with a third gate pitch greater than the first and second gate pitches. The etch stop layer may be implanted with a stress-altering material from a second oblique angle that is less than the first oblique angle.

The first angle may be about 70 degrees and the second angle may be about 60 degrees.

The stress-altering material may include at least one of Ge, carbon (C), xenon (Xe) or fluorine (F) ions.

A greater amount of the stress-altering material may reach portions of the etch stop layer that are not shadowed at the oblique angle.

The oblique angle may be between about 20 and about 80 degrees.

The etch stop layer between each of the second plurality of transistors may receive a greater amount of the stress-altering material than the etch stop layer between each of the first plurality of transistors.

The first and second pluralities of transistors may be NFETs and the ESL may be tensile.

The method may further include forming PFETs on a same substrate as the NFETs, forming a compressive ESL above the PFETs, and ion-implanting the tensile and compressive ESLs with the same material for stress relaxation.

In accordance with an exemplary embodiment of the present inventive concept an electronic subsystem includes a host coupled to a memory system having a memory controller coupled to a memory device, the memory device including at least one semiconductor device as described above.

The host may be a mobile device or a processing device having a processor.

The electronic subsystem may further include a wireless interface for communicating with a cellular device.

The electronic subsystem may further include a connector for removably connecting to a host system, wherein the host system is one of a personal computer, notebook computer, hand held computing device, camera, or audio reproducing device.

The wireless interface may communicate using a communication interface protocol of a third generation communication system, including one of code division multiple access (CDMA), global system for mobile communications (GSM), north American digital cellular (NADC), extended-time division multiple access (E-TDMA), wide band code division multiple access (WCDMA), or CDMA2000.

In accordance with an exemplary embodiment of the present inventive concept an electronic subsystem includes a printed circuit board supporting a memory unit, a device interface unit and an electrical connector, the memory unit having a memory that has memory cells arranged on the printed circuit board, the device interface unit being electrically connected to the memory unit and to the electrical connector through the printed circuit board, at least one of the memory unit and device interface unit comprising a semiconductor device having at least one semiconductor device as described above.

### BRIEF DESCRIPTION OF THE DRAWINGS

Exemplary embodiments of the present inventive concept will be more clearly understood from the following detailed description taken in conjunction with the accompanying drawings in which:

FIGS. 1, 2, 3, 4, 5 and 6 show a fabrication process and resultant semiconductor device according to an exemplary embodiment of the present inventive concept;

FIG. 7 shows a semiconductor device according to an exemplary embodiment of the present inventive concept; and

FIGS. 8, 9, 10, 11, 12 and 13 show various circuit and electronic subsystem diagrams, each of which may implement at least one of the exemplary embodiments described herein.

### DETAILED DESCRIPTION OF THE EMBODIMENTS

Reference will now be made in detail to the exemplary embodiments, examples of which are illustrated in the accompanying drawings, wherein like reference numerals refer to the like elements throughout.

However, the present inventive concept may be embodied in many different forms and should not be construed as limited to the exemplary embodiments set forth herein. Rather, these embodiments are provided so that this disclosure will be thorough and complete, and will fully convey the scope of the inventive concept to those skilled in the art.

In the figures, the dimensions of layers and regions may be exaggerated for clarity. It will be understood that when a layer or element is referred to as being “on” another layer or element, it can be directly on the other layer or element, or intervening layers may also be present. Further, it will be understood that when a layer is referred to as being “under” another layer or element, it can be directly under the layer or element, or one or more intervening layers or elements may also be present. In addition, it will be understood that when a layer or an element is referred to as being “between” two layers or elements, it can be the only layer between the two layers or elements, or one or more intervening layers or elements may also be present. Like reference numerals refer to like elements throughout.

It will be understood that the order in which the steps of each fabrication method according to an exemplary embodiment of the present inventive concept disclosed in this disclosure are performed is not restricted to those set forth herein, unless specifically mentioned otherwise. Accordingly, the order in which the steps of each fabrication method according to an exemplary embodiment of the present inventive concept disclosed in this disclosure are performed can be varied.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present inventive concept. As used herein, the term “and/or” includes any and all combinations of one or more of the associated listed items.

It will be understood that when an element is referred to as “covering” another element, it can immediately cover the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

Unless otherwise defined, all terms (including technical and scientific terms) used herein have the same meaning as commonly understood by one of ordinary skill in the art to which the exemplary embodiments of the present inventive concept belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

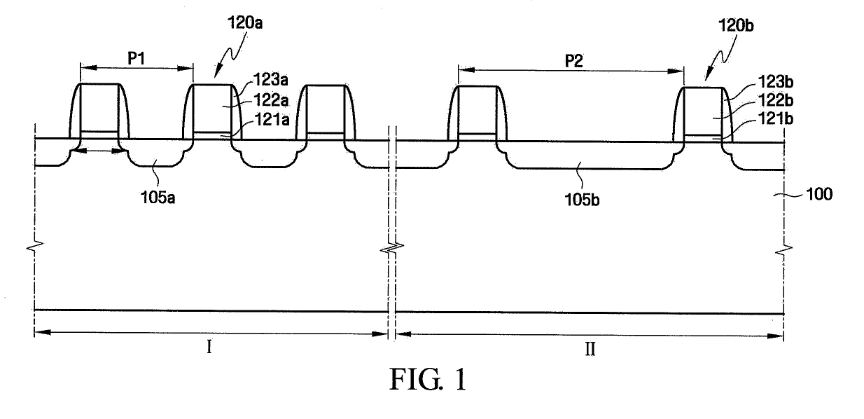

Referring now to FIGS. 1-6, there is shown a fabrication process for a semiconductor device according to an exemplary embodiment of the present inventive concept.

In FIG. 1 a semiconductor substrate 100 having transistors is provided divided into two regions I, II. The regions may form NFETs, and/or PFETs. Region I includes transistors 120a spaced apart from each other by a gate-to-gate pitch P1. Region II includes transistors 120b spaced apart from each other by a gate-to-gate pitch P2. P1 is finer than P2. In an exemplary embodiment P1=45 nm, while P2=90 nm.

Transistors 120a each include source/drains 105a and gates having gate insulation films 121a, gate electrodes 122a and spacers 123a. Transistors 120b each include source/drains105b and gates having gate insulation films 121b, gate electrodes 122b and spacers 123b.

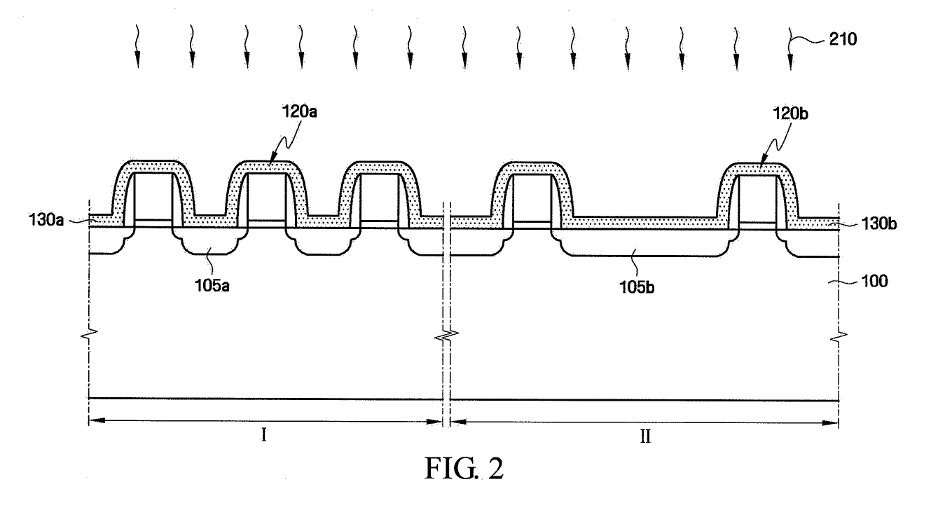

Referring now to FIG. 2, in an exemplary embodiment stress layers 130a, 130b are formed over gates 120a, 120b and source/drains 105a, 105b. The stress layers may be made of a material that accumulate a stress on the silicon substrate. A thermal process 210 is then applied to stress layers 130a, 130b. In an alternative exemplary embodiment the stress layers may be eliminated, for example, for a PFET device.

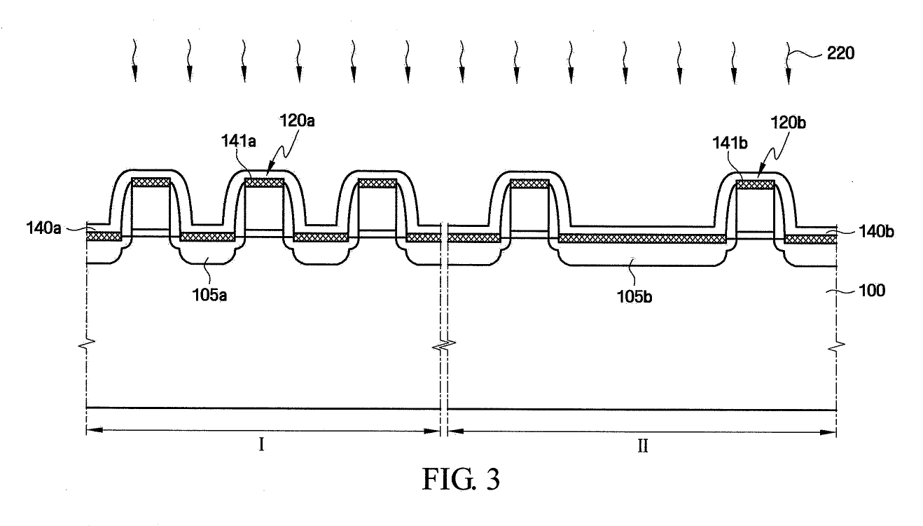

In FIG. 3, a silicidation process is then performed to provide silicide layers 141a, 141b on exposed materials including gate electrodes 120a, 120b and source/drains 105a, 105b in both regions I, II. The silicide layers may be metal silicide layers including metals such as Ti, Co, Ni and the like. Metal layers 140a, 140b are then formed over the gate electrodes, including spacers thereon, and over the source/drains in both regions I, II. A thermal process 220 is then performed on both regions I, II.

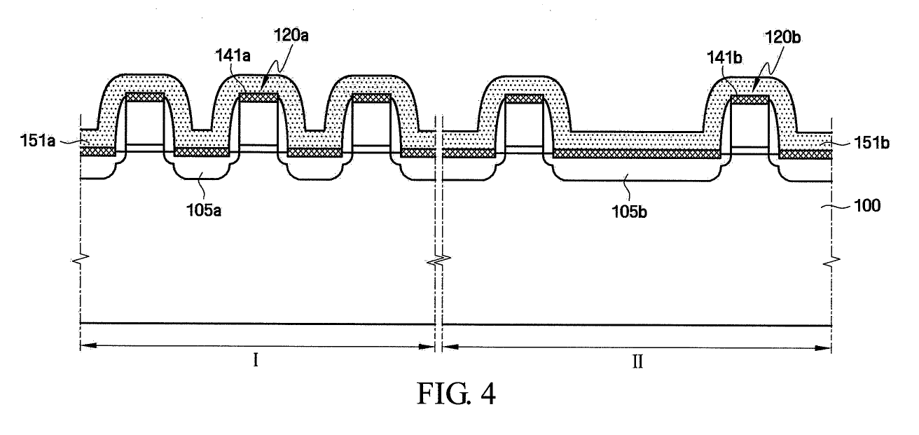

Referring now to FIG. 4, after the silicidation process, tensile SiN 600 Å layers 151a, 151b, which act as contact etch stop layers (ESLs), are provided on the silicon substrate in both regions I, II.

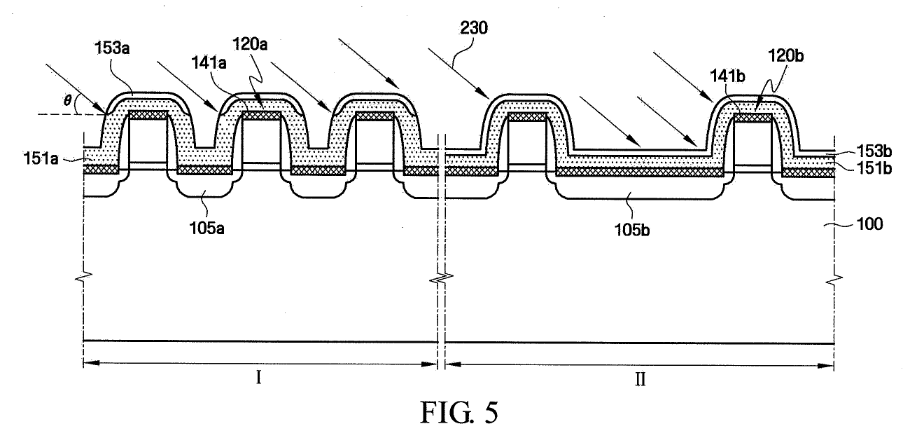

As seen in FIG. 5, in an exemplary embodiment Ge ions 230 are implanted into regions I, II at an oblique angle θ. In an exemplary embodiment, the oblique angle θ is between about 20° and about 80°. In a particular exemplary embodiment, the oblique angle can be 70°. Due to the shadowing effect in region I resulting from the finer pitch P1, there is only a partial Ge ion penetration 153a in region I, while there is a full Ge ion penetration 153b in region II. The partial penetration of the Ge ions into the ESL does not significantly change the stress effect, while the full Ge ion penetration can provide a substantial relaxation of the stress. In alternative embodiments C, Xe and F ion implantations may be utilized.

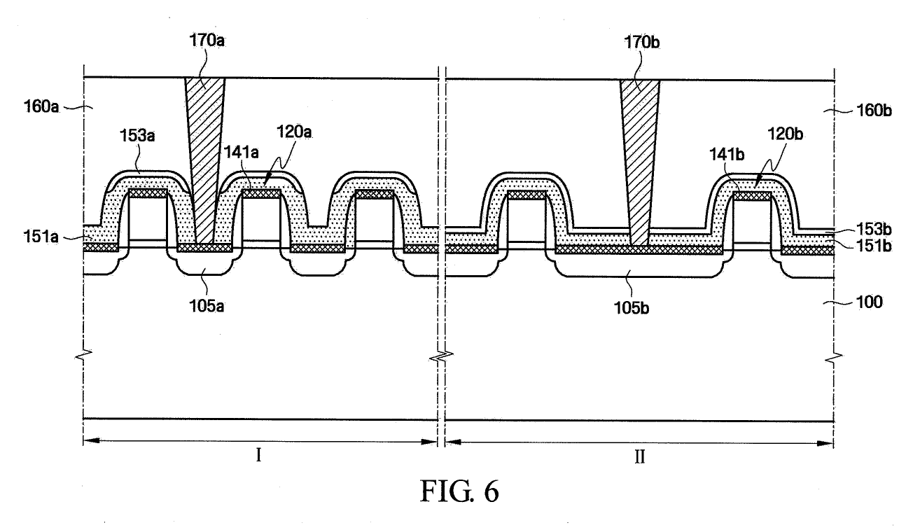

Referring now to FIG. 6, a contact forming process is then conducted. Inter dielectric layers 160a, 160b are formed on the ESLs 151a, 151b. Contact holes are formed over the sources/drains 105a, 105b and metal contact plugs 170a, 170b are formed in the contact holes.

Those skilled in the art will appreciate that due to the Poly Spacing Effect (PSE), that is, the difference of stress effect between regions having different gate-to-gate pitches, the transistor performance may vary. Typically, if there is a PSE above +/−0.05 the transistors may not operate in a sufficiently uniform manner. For example, in an NFET device having a 1X gate-to-gate pitch and a 2X gate-to-gate pitch the stress in the 1X case would be less than the stress in the 2X case and the transistor performance of the two regions would not be uniform. In an exemplary embodiment, if the 1X gate-to-gate pitch difference was 45 nm, and the 2X gate-to-gate pitch was 90 nm, the PSE for a NFET might be about 1.15 and the PSE for PFET might be about −0.93.

However, in accordance with the present inventive concept, the semiconductor device fabricated as described herein optimizes uniformity of transistor performance by the utilization of tilted ion implantation into the ESL layer to adjust stress relaxation and take into account the PSE. When comparing the stress relaxation resulting from the tilted Ge implantation of regions I and II of FIG. 5, an ESL of SiN having 600 Å thickness and having a 1X gate-to-gate pitch provides partial stress relaxation, while the ESL of SiN having 600 Å thickness and having a 2X gate-to-gate pitch provides an overall stress relaxation effect. The resultant semiconductor device can have improved performance uniformity as a result of the selective stress relaxation of the ESL in accordance with the present inventive concept.

Those skilled in the art will appreciate that in an exemplary embodiment the etch stop layer may include an upper etch stop layer disposed on a lower etch stop layer with the upper etch stop layer having a greater proportion of a stress-altering material than the lower etch stop layer. The upper etch stop layer may be configured in an exemplary embodiment to have a stress reduction relative to the lower etch stop layer. The upper etch stop layer may be configured to have more Ge relative to the lower etch stop layer. The upper etch stop layer may be configured to be about half as thick as the lower etch stop layer. In addition, in an exemplary embodiment the ion implantation could result in the equivalent of two etch stop layers by having a heavier ion concentration toward the lower portion of the etch stop layer.

Those skilled in the art will appreciate that in crystalline solids, the atoms which make up the solid are spatially arranged in a periodic fashion called a lattice. A crystal lattice contains a volume, which is representative of the entire lattice and is regularly repeated throughout the crystal. In describing crystalline semiconductor materials in the present disclosure, the following conventions are typically used. The directions in a lattice are expressed as a set of three integers with the same relationship as the components of a vector in that direction. For example, in cubic lattices, such as silicon, that has a diamond crystal lattice, a body diagonal exists along the [111] direction with the [ ] brackets denoting a specific direction.

Those skilled in the art will also appreciate that the transistors in regions I, II may be NFETs disposed on substrate and have a first channel direction aligned with respect to a crystal direction of the substrate, while PFETs may be disposed on the substrate having a second channel direction aligned with respect to the crystal direction of the substrate. In an exemplary embodiment the second channel direction is about 45 degrees offset from the first channel direction. In an exemplary embodiment the first substrate may have a [110] crystal direction and the second substrate may have a rotated [100] crystal direction.

Further, the transistors in the regions I, II may be NFETs having a tensile etch stop layer, and further include PFETs on the same substrate as the NFETs, the PFETs having a compressive etch stop layer. In an exemplary embodiment the tensile etch stop layer and the compressive etch stop layer may have the same ion implantation for stress relaxation.

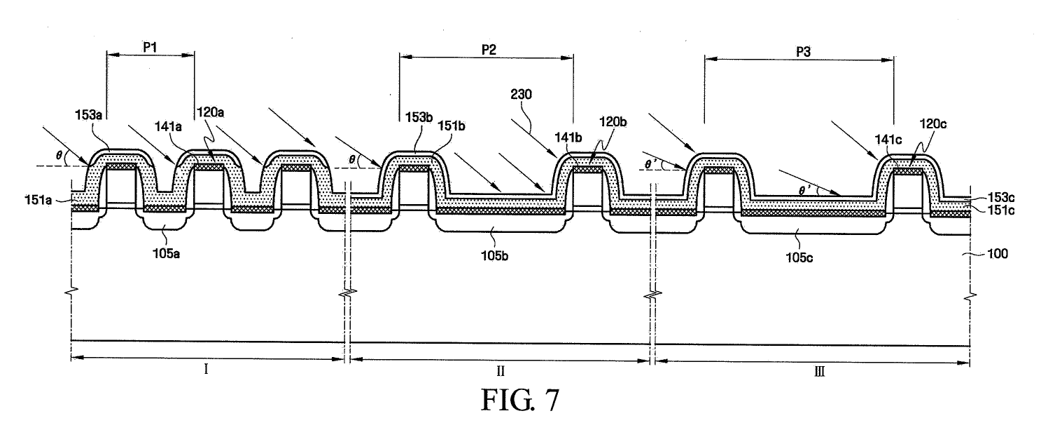

Referring now to FIG. 7, a third plurality of transistors in region III can be spaced with a third gate pitch P3 greater than the first and second gate pitches, P1, P2 in regions I, II. Otherwise, FIG. 7 is similar to FIG. 6, so duplicate description shall be omitted.

Here, an additional etch stop layer (ESL) 151c can be implemented over an additional source/drain region 105c by depositing a stress-altering material from a second oblique angle θ′ that is less than the first oblique angle θ. Thus, the additional ESL is substantially blocked from reaching the source/drain regions 105a and 105b due to the tighter pitch there.

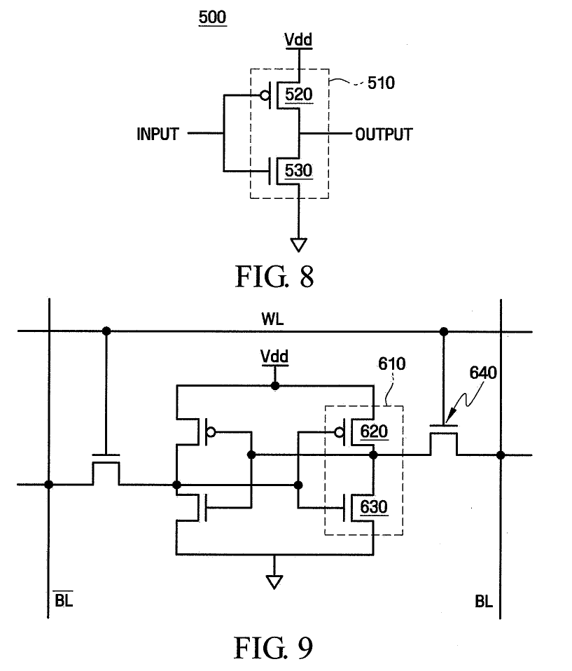

Referring now to FIGS. 8-13, there are depicted various circuit and electronic subsystem diagrams, each of which may implement at least one of the exemplary embodiments described above.

FIG. 8 shows CMOS inverter 500, having an input and output coupled to CMOS structure 510 which contains PFET portion 520 an NFET portion 530. The digital inverter may be considered the basic building block for all digital electronics. Memory (1 bit register) is built as a latch by feeding the output of two serial inverters together. Multiplexers, decoders, state machines, and other sophisticated digital devices all rely on the basic inverter. In digital logic, an inverter or NOT gate is a logic gate which implements logical negation. The non-ideal transition region behavior of the CMOS inverter makes it useful in analog electronics as the output stage of an operational amplifier. The inverter circuit outputs a voltage representing the opposite logic-level to its input. Inverters can be constructed using two complimentary transistors in the CMOS configuration as depicted in FIG. 7. This configuration greatly reduces power consumption since one of the transistors is always off in both logic states. Processing speed can also be improved due to the relatively low resistance compared to the NFET-only or PFET-only type devices. Inverters can also be constructed with Bipolar Junction Transistors (BJT) in either a resistor-transistor logic (RTL) or a transistor-transistor logic (TTL) configuration. Therefore, by implementing the CMOS inverter circuit in accordance with at least one exemplary embodiment of the present inventive concept, the fabricated CMOS inverter circuit can have improved semiconductor performance uniformity.

FIG. 9 shows a CMOS static random access memory (SRAM) circuit having CMOS circuit 610 with PFET portion 620 and NFET portion 630 coupled to transistor 640. The SRAM is a type of semiconductor memory that does not need to be periodically refreshed. Each bit in an SRAM is stored on four transistors that form two cross-coupled inverters as shown in FIG. 8. This storage cell has two stable states which are used to denote 0 and 1. Two additional access transistors serve to control the access to a storage cell during read and write operations. The power consumption of SRAM varies widely depending on how frequently it is accessed. Many categories of industrial and scientific subsystems and automotive electronics contain SRAMs. Some are also embedded in practically all modern appliances, toys, etc that implements an electronic user interface. Several megabytes may be used in electronic products such as digital cameras, cell phones, synthesizers, etc. SRAMs are also used in personal computers, workstations, routers and peripheral equipment, internal CPU caches, external burst mode SRAM caches, hard disk buffers and router buffers, LCD screens and printers also normally employ static RAM to hold the image displayed (or to be printed). Small SRAM buffers are also found in CDROM and CDRW drives, usually 256 kB or more are used to buffer track data, which is transferred in blocks instead of as single values. The same applies to cable modems and similar equipment connected to computers. Therefore, by implementing the CMOS SRAM circuit in accordance with at least one exemplary embodiment of the present inventive concept, the fabricated CMOS SRAM circuit can have improved semiconductor performance uniformity.

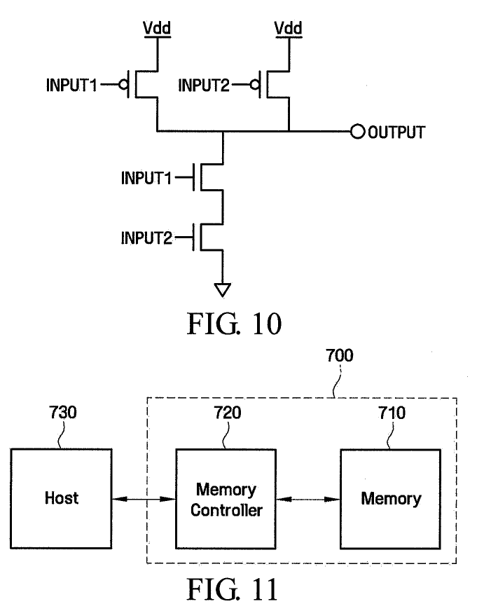

FIG. 10 shows a CMOS NAND circuit. Those skilled in the art will appreciate that the NAND gate is the easiest to manufacture, and also has the property of functional completeness. That is, any other logic function (AND, OR, etc.) can be implemented using only NAND gates. An entire processor can be created using NAND gates alone. Therefore, by implementing the NAND circuit in accordance with at least one exemplary embodiment of the present inventive concept, the fabricated NAND circuit can have improved semiconductor performance uniformity.

Referring now to FIGS. 11-13, various electronic subsystems are depicted.

FIG. 11 shows an electronic subsystem which includes a semiconductor device according to at least one exemplary embodiment of the present inventive concept. Electronic subsystem 700 includes a memory controller 720 and a memory 710, either of which may have a structure according to at least one exemplary embodiment of the present inventive concept. The memory controller 720 controls the memory device 710 to read or write data from/into the memory 710 in response to a read/write request of a host 730. The memory controller 720 may include an address mapping table for mapping an address provided from the host 730 (e.g., mobile devices or computer systems) into a physical address of the memory device 710.

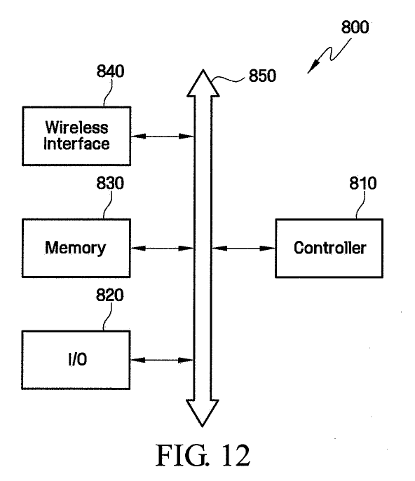

Referring to FIG. 12, an electronic subsystem including a semiconductor device according to at least one exemplary embodiment of the present inventive concept will now be described. Electronic subsystem 800 may be used in a wireless communication device (e.g., a personal digital assistant, a laptop computer, a portable computer, a web tablet, a wireless telephone, a mobile phone and/or a wireless digital music player.) or in any device capable of transmitting and/or receiving information via wireless environments.

The electronic subsystem 800 includes a controller 810, an input/output (I/O) device 820 (e.g., a keypad, a keyboard, and a display), a memory 830, and a wireless interface 840, each device being coupled to a communication bus 850 and may have a structure according to at least one exemplary embodiment of the present inventive concept. The controller 810 may include at least one of a microprocessor, a digital signal processor, or a similar processing device. The memory 830 may be used to store commands executed by the controller 810, for example. The memory 830 may be used to store user data. The electronic system 800 may utilize the wireless interface 840 to transmit/receive data via a wireless communication network. For example, the wireless interface 840 may include an antenna and/or a wireless transceiver. The electronic system 800 according to exemplary embodiments may be used in a communication interface protocol of a third generation communication system, e.g., code division multiple access (CDMA), global system for mobile communications (GSM), north American digital cellular (NADC), extended-time division multiple access (E-TDMA) and/or wide band code division multiple access (WCDMA), CDMA2000.

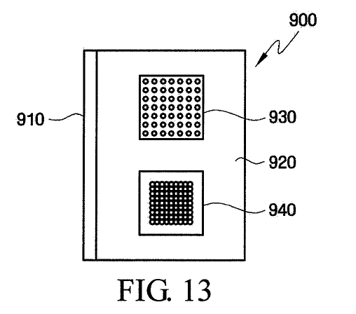

Referring to FIG. 13, an electronic subsystem including a semiconductor device according to at least one exemplary embodiment of the present inventive concept will now be described. Electronic subsystem 900 may be a modular memory device and includes a printed circuit board 920. The printed circuit board 920 may form one of the external surfaces of the modular memory device 900. The printed circuit board 920 may support a memory unit 930, a device interface unit 940, and an electrical connector 910.

The memory unit 930 may have a various data storage structures, including at least one exemplary embodiment of the present inventive concept, and may include a three-dimensional memory array and may be connected to a memory array controller. The memory array may include the appropriate number of memory cells arranged in a three-dimensional lattice on the printed circuit board 920. The device interface unit 940 may be formed on a separated substrate such that the device interface unit 940 may be electrically connected to the memory unit 930 and the electrical connector 910 through the printed circuit board 920. Additionally, the memory unit 930 and the device interface unit 940 may be directly mounted on the printed circuit board 920. The device interface unit 940 may include components necessary for generating voltages, clock frequencies, and protocol logic.

Therefore, by implementing any one of the above-described electronic subsystems with components in accordance with at least one exemplary embodiment of the present inventive concept, the fabricated components can have improved semiconductor performance uniformity.

While exemplary embodiments have been particularly shown and described, it will be understood that various changes in form and details may be made therein without departing from the spirit and scope of the following claims.

What is claimed is:

1. A strained semiconductor device comprising:
a first plurality of transistors spaced with a first gate pitch;
a second plurality of transistors spaced with a second gate pitch greater than the first gate pitch; and
an etch stop layer disposed on the first and second pluralities of transistors,
wherein the etch stop layer between each of the second plurality of transistors has a different proportion of a stress-altering material than the etch stop layer between each of the first plurality of transistors.

2. The device of claim 1 wherein the etch stop layer between each of the first plurality of transistors has substantially the same stress as the etch stop layer between each of the second plurality of transistors.

3. The device of claim 1 wherein portions of the etch stop layer shadowed from an oblique angle have a lesser proportion of a stress-altering material than portions of the etch stop layer that are not shadowed from the oblique angle.

4. The device of claim 1 wherein the etch stop layer between each of the first plurality of transistors has a lesser proportion of Germanium than the etch stop layer between each of the second plurality of transistors.

5. The device of claim 1 wherein the transistors are negative channel field effect transistors (NFETs).

6. The device of claim 1 wherein the etch stop layer comprises an upper etch stop layer disposed on a lower etch stop layer, and the upper etch stop layer has a greater proportion of a stress-altering material than the lower etch stop layer.

7. The device of claim 6 wherein the upper etch stop layer has a stress reduction relative to the lower etch stop layer.

8. The device of claim 6 wherein the upper etch stop layer has more germanium (Ge) relative to the lower etch stop layer.

9. The device of claim 6 wherein the upper etch stop layer is about half as thick as the lower etch stop layer.

10. The device of claim 1 wherein the first and second pluralities of transistors are negative channel field effect transistors (NFETs) disposed on substrate and having a first channel direction aligned with respect to a crystal direction of the substrate, the device further comprising positive channel field effect transistors (PFETs) disposed on the substrate having a second channel direction aligned with respect to the crystal direction of the substrate.

11. The device of claim 10 wherein the second channel direction is about 45 degrees offset from the first channel direction.

12. The device of claim 10 wherein the first substrate has a normal [110] crystal direction and the second substrate has a rotated [100] crystal direction.

13. The device of claim 1 wherein the first and second pluralities of transistors are negative channel field effect transistors (NFETs) having a tensile etch stop layer, the device further comprising positive channel effect transistors (PFETs) on a same substrate as the NFETs, the PFETs having a compressive etch stop layer.

14. The device of claim 13 wherein the tensile etch stop layer and the compressive etch stop layer have the same ion implantation for stress relaxation.

15. The device of claim 13 wherein the ion is germanium (Ge).

16. A method of manufacturing a strained semiconductor device, the method comprising:
forming a first plurality of transistors spaced with a first gate pitch;
forming a second plurality of transistors spaced with a second gate pitch greater than the first gate pitch;
depositing an etch stop layer on the first and second pluralities of transistors; and
implanting the etch stop layer from an oblique angle with a stress-altering material.

17. The method of claim 16 wherein the oblique angle is about 70 degrees for a 45 nm device having transistors with 1X and 2X gate pitches.

18. The method of claim 16 forming a third plurality of transistors spaced with a third gate pitch greater than the first and second gate pitches; and
implanting the etch stop layer with a stress-altering material from a second oblique angle that is less than the first oblique angle.

19. The method of claim 18 wherein the first angle is about 70 degrees and the second angle is about 60 degrees.

20. The method of claim 16 wherein the stress-altering material comprises at least one of germanium (Ge), carbon (C), xenon (Xe) or fluorine (F) ions.

21. The method of claim 16 wherein a greater amount of the stress-altering material reaches portions of the etch stop layer that are not shadowed at the oblique angle.

22. The method of claim 16 wherein the oblique angle is between about 20 and about 80 degrees.

23. The method of claim 16 wherein the etch stop layer between each of the second plurality of transistors receives a greater amount of the stress-altering material than the etch stop layer between each of the first plurality of transistors.

24. The method of claim 16 wherein the first and second pluralities of transistors are negative channel effect transistors (NFETs) and the etch stop layer is tensile, the method further comprising:
forming positive channel effect transistors (PFETs) on a same substrate as the NFETs;
forming a compressive etch stop layer above the PFETs;
ion-implanting the tensile etch stop layer and the compressive etch stop layer with the same material for stress relaxation.

25. An electronic subsystem comprising a host coupled to a memory system having a memory controller coupled to a memory device, the memory device comprising at least one semiconductor device having:
a first plurality of transistors spaced with a first gate pitch;
a second plurality of transistors spaced with a second gate pitch greater than the first gate pitch; and
an etch stop layer disposed on the first and second pluralities of transistors,
wherein the etch stop layer between each of the second plurality of transistors has a greater proportion of a stress-altering material than the etch stop layer between each of the first plurality of transistors.

26. The electronic subsystem of claim 25, wherein the host is a mobile device or a processing device having a processor.

27. The electronic subsystem of claim 25, further comprising a wireless interface for communicating with a cellular device.

28. The electronic subsystem of claim 25, further comprising a connector for removably connecting to a host system, wherein the host system is one of a personal computer, notebook computer, hand held computing device, camera, or audio reproducing device.

29. The electronic device of claim 27, wherein the wireless interface communicates using a communication interface protocol of a third generation communication system, including one of code division multiple access (CDMA), global system for mobile communications (GSM), north American digital cellular (NADC), extended-time division multiple access (E-TDMA), wide band code division multiple access (WCDMA), or CDMA2000.

30. An electronic subsystem comprising a printed circuit board supporting a memory unit, a device interface unit and an electrical connector, the memory unit having a memory that has memory cells arranged on the printed circuit board, the device interface unit being electrically connected to the memory unit and to the electrical connector through the printed circuit board, at least one of the memory unit and device interface unit comprising a at least one semiconductor device having:
a first plurality of transistors spaced with a first gate pitch;
a second plurality of transistors spaced with a second gate pitch greater than the first gate pitch; and
an etch stop layer disposed on the first and second pluralities of transistors,
wherein the etch stop layer between each of the second plurality of transistors has a greater proportion of a stress-altering material than the etch stop layer between each of the first plurality of transistors.
